(19) United States
(12) Patent Application Publication
(10) Pub. No.: US 2026/0002994 A1
(43) Pub. Date: Jan. 1, 2026

(54) TEST APPARATUS AND TEST COVER THEREOF

(71) Applicant: SILICONWARE PRECISION INDUSTRIES CO., LTD., Taichung City (TW)

(72) Inventors: Wu-Su CHEN, Taichung City (TW); Shih-Sheng LUO, Taichung City (TW); Hui-Lung CHEN, Taichung City (TW); Tz-Chi YU, Taichung City (TW)

(21) Appl. No.: 18/920,306

(22) Filed: Oct. 18, 2024

(30) Foreign Application Priority Data
Jun. 28, 2024 (TW) 113124396

(51) Int. Cl. G01R 31/327; G01R 31/00

(52) U.S. Cl. CPC G01R 31/3278; G01R 31/001

(57) ABSTRACT

A test apparatus and a test cover thereof are provided for electrical testing of a relay on a carrier board. The test cover includes a sleeve and a plurality of contacts. The sleeve is used to sleeve-couple to the relay. The plurality of contacts are disposed at an end of the sleeve and protrude from the sleeve and are used to contact and be electrically connected to a plurality of pins of the relay when the sleeve is sleeve-coupled to the relay for electrical testing. The test apparatus is capable of performing directly electrical test on the relay on the carrier board without the need for desoldering or dismantling the relay prior to performing electrical test. Therefore, the time required for addressing abnormal events during electronic component testing can be reduced, and the hazards associated with desoldering or dismantling the carrier board can be prevented.

### CROSS-REFERENCE TO RELATED APPLICATIONS

The present application is based upon and claims the right of priority to TW Patent Application No. 113124396, filed June 28, 2024, the disclosure of which is hereby incorporated by reference herein in its entirety for all purposes.

### BACKGROUND

### 1. Technical Field

The present disclosure relates to a test apparatus, and more particularly, to a test apparatus and a test cover thereof for a relay.

### 2. Description of Related Art

In recent years, with the continuous maturation and development of semiconductor process technology, various high-performance electronic products have been continuously introduced, and the functions of these electronic products have evolved toward user-friendliness and multi-functionality. However, within electronic products, there are various electronic components with different functions, such as integrated circuits (ICs). In the manufacturing process of electronic components, IC packaging plays a pivotal role. IC packaging types can be broadly classified into two categories: pin-in-hole (PIH) and surface mount technology (SMT). Among these, the PIH is such as dual in-line package (DIP) and pin grid array (PGA) package, while the SMT is such as wire bonding (WB) package, tape automatic bonding (TAB) package, flip chip (FC), ball grid array (BGA) package, and fan-out packaging structure. Each of these packaging forms possesses distinctive characteristics and application fields.

However, regardless of the packaging form, semiconductor chips containing integrated circuits must undergo an electrical test before being provided on a packaging substrate or a carrier board to ensure that a good chip is provided on a good carrier board, thus facilitating the production of quality products. During the electrical test, the chip is mounted on the carrier board (i.e., the circuit board) of the test machine. The carrier board serves as the transmission medium between the integrated circuit and the test apparatus, thereby electrically testing the signals, functions, and characteristics of the integrated circuit.

A plurality of relays are provided on the carrier board and have the function of opening/closing circuits or switching circuits, and can be electrically connected to the chip under test to a variety of test circuits to perform various tests. In the event of an abnormality in the relay on the carrier board, according to the existing technology and without desoldering or dismantling the relay, only a multimeter can be used to measure to confirm whether the switching (current passing) function of the relay can work. Nevertheless, it is not feasible to measure the electrical values, such as operating time and release time. In order to measure the aforementioned electrical values, it is necessary to desolder or dismantle the relays on the carrier board one by one and then use special test apparatus to measure them. This not only takes a lot of time, but also runs the risk of damaging the relay and the carrier board. Consequently, the aforementioned problems have become an urgent issue for the industry to solve.

### SUMMARY

In view of the various deficiencies of the prior art, the present disclosure provides a test cover for electrical testing of a relay on a carrier board. The test cover includes a sleeve and a plurality of contacts. The sleeve is used to sleeve-couple to the relay. The plurality of contacts are disposed at an end of the sleeve and protrude from the sleeve, and used to contact and be electrically connected to a plurality of pins of the relay as the sleeve is sleeve-coupled to the relay for electrical testing.

The present disclosure also provides a test apparatus for electrical testing of a relay on a carrier board. The test apparatus includes a test device, an interface device, and a test cover. The test device is used to perform an electrical test and to receive an electrical signal outputted from the relay during the electrical test. The interface device is electrically connected to the test device to actuate the test device to perform the electrical test and to display the electrical signal. The test cover is electrically connected to the test device and includes a sleeve and a plurality of contacts. The sleeve is used to sleeve-couple to the relay. The plurality of contacts are disposed at an end of the sleeve and protrude from the sleeve, and used to contact and be electrically connected to a plurality of pins of the relay as the sleeve is sleeve-coupled to the relay for transmitting the electrical signal from the plurality of pins to the test device.

The test apparatus of the present disclosure is capable of performing directly the electrical test on the relay on the carrier board without the need for desoldering or dismantling the relay prior to performing the electrical test. Therefore, the time required for addressing abnormal events during electronic component testing can be reduced, and the hazards associated with desoldering or dismantling the carrier board can be prevented.

### BRIEF DESCRIPTION OF THE DRAWINGS

FIG. 1 is a block diagram illustrating a test apparatus according to an embodiment of the present disclosure.

FIG. 2 is a schematic view illustrating a carrier board for applying a test apparatus according to an embodiment of the present disclosure.

FIG. 3 is a schematic view with an elevation angle illustrating a test cover and a relay according to an embodiment of the present disclosure.

FIG. 4 is a schematic view with an elevation angle illustrating a test cover sleeve-coupled to a relay according to an embodiment of the present disclosure.

### DETAILED DESCRIPTION

Embodiments of the present disclosure are described below with specific examples. Those skilled in the art can easily understand other advantages and effects of the present disclosure from the contents disclosed in this specification.

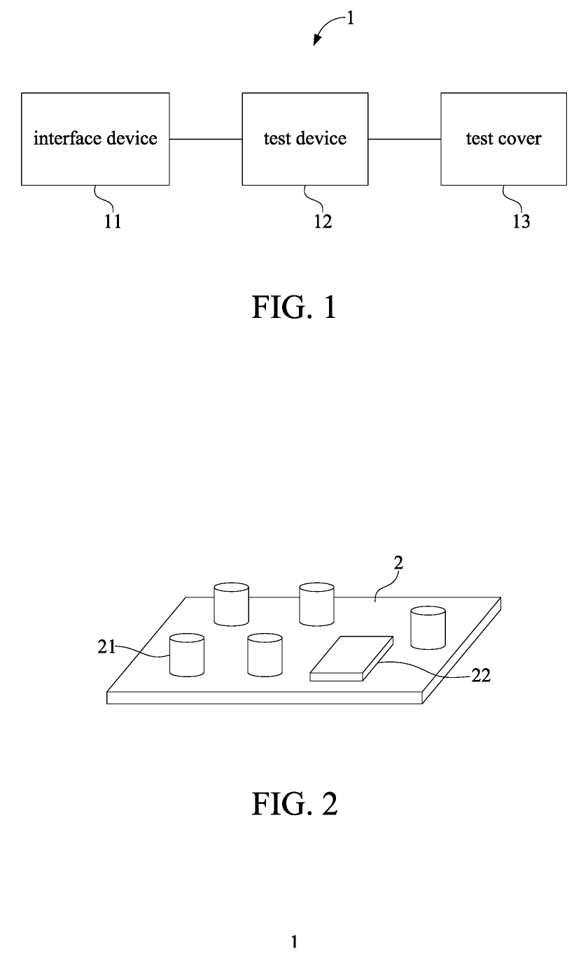

FIG. 1 is a block diagram illustrating a test apparatus 1 according to an embodiment of the present disclosure. FIG. 2 is a schematic view illustrating a carrier board 2 (a circuit board having circuit layers) for applying the test apparatus 1 according to an embodiment of the present disclosure. Referring to FIG. 1 and FIG. 2, the test apparatus 1 includes an interface device 11, a test device 12, and a test cover 13. The test device 12 is electrically connected to the interface device 11 and the test cover 13 via signal wirings. The interface device 11 may be an electronic device such as a computer or a mobile device (e.g., a cell phone), and etc.

The test apparatus 1 can be used for electrical testing of a relay 21 on the carrier board 2. As shown in FIG. 2, a plurality of relays 21 and an electronic component socket 22 are disposed on the carrier board 2. The electronic component socket 22 is used to mount an electronic component under test, such as a semiconductor chip including integrated circuits. The relay 21 is used to be electrically connected to the electronic component socket 22 and various test circuits (not shown) of the carrier board 2 to test various functions of the electronic component.

The electrical testing of the relay 21 includes a measurement of whether the relay 21 switches between an on state and an off state (in short, whether it can let current pass) according to the control of the test device 12, and includes a measurement of electrical values of the relay 21. The electrical values may include values such as an operating/response time and a release/reset time of the relay 21.

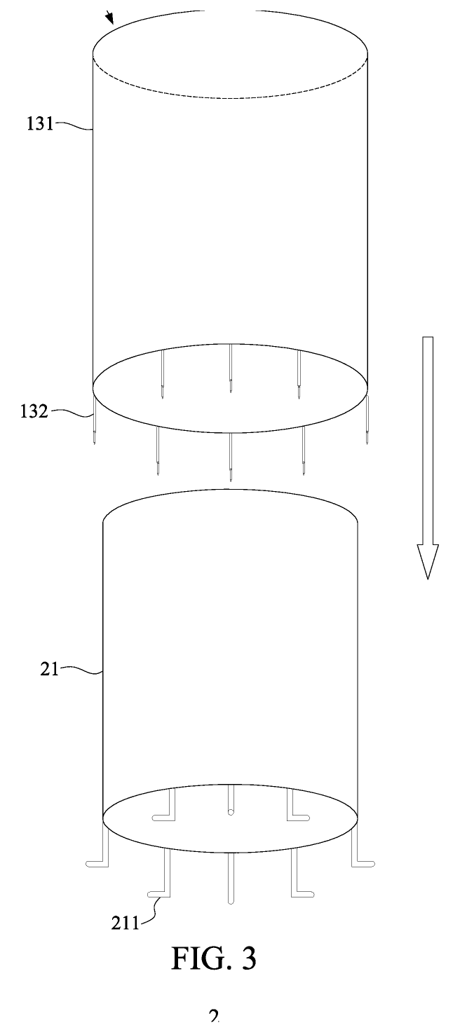

Please also refer to FIG. 3, which is a schematic view with an elevation angle illustrating a test cover 13 and a relay 21 according to an embodiment of the present disclosure. Only one relay 21 is shown in FIG. 3 as an example, since each of the relays 21 on the carrier board 2 has the same or similar structure. As shown in FIG. 3, the relay 21 includes a plurality of pins 211, and the relay 21 is electrically connected to the electronic component socket 22 and the above-mentioned test circuits via the plurality of pins 211.

Specifically, as shown in FIG. 3, the test cover 13 includes a sleeve 131 and a plurality of contacts 132. The sleeve 131 is used to be sleeve-coupled to the relay 21. The plurality of contacts 132 are disposed at an end of the sleeve 131, i.e. a lower end in FIG. 3, and protrude from the sleeve 131. A material forming the sleeve 131 is an antistatic material, such as polyetherimide (PEI) or other antistatic engineering plastics, which can prevent static electricity from damaging the relay 21. Each of the contacts 132 of the test cover 13 is in an elongated shape of a post, a pin, or a cone. For example, each of the contacts 132 shown in FIG. 3 is a spring-loaded pin (a pogo pin) made of an electrically conductive material (e.g., metal) to provide a better signal transmission effect upon contact.

The test device 12 controls the relay 21 via the contacts 132 of the test cover 13 to perform an electrical test on the relay 21. The test device 12 receives an electrical signal outputted from the relay 21 via the test cover 13 during the electrical test.

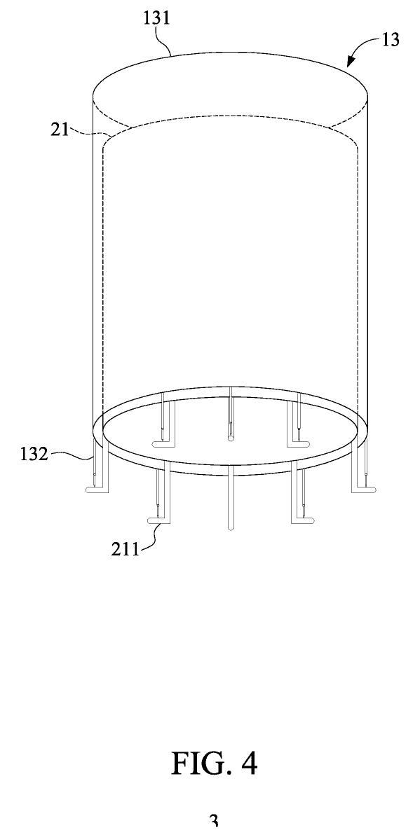

During operation, the test cover 13 is sleeve-coupled on the relay 21 downward from above, so that the sleeve 131 is sleeve-coupled to the relay 21. As shown in FIG. 4, when the sleeve 131 is sleeve-coupled to the relay 21, the plurality of contacts 132 contact and are electrically connected to the plurality of pins 211 of the relay 21. The plurality of contacts 132 of the test cover 13 are disposed at the end of the sleeve 131 at locations corresponding to the plurality of pins 211 of the relay 21, and a quantity of the plurality of contacts 132 of the test cover 13 is equal to a quantity of the plurality of pins 211 of the relay 21. Accordingly, there is a one-to-one correspondence between the plurality of contacts 132 of the test cover 13 and the plurality of pins 211 of the relay 21. Each of the contacts 132 of the test cover 13 contacts and is electrically connected to a corresponding pin 211 of the relay 21 when the sleeve 131 is sleeve-coupled to the relay 21. For example, in FIG. 4, each contact 132 can contact and is electrically connected to its corresponding pin 211 from above or from a side in FIG. 4. In addition, each contact 132 is electrically connected to the test device 12 via a signal wiring. Thus, during the electrical test, the contacts 132 of the test cover 13 transmit the electrical signals inputted by the test device 12 into the relay 21 to the pins 211 of the relay 21 and transmit the electrical signals outputted by the relay 21 from its pins 211 back to the test device 12.

The interface device 11 may provide a user interface for receiving an operation from a tester, based on which the interface device 11 may command the test device 12 to perform the electrical test. In addition, the interface device 11 may obtain from the test device 12 an electrical signal inputted to the relay 21 by the test device 12 and an electrical signal outputted from the relay 21 during the electrical test, and display the aforementioned electrical signals on the user interface. Thus, the tester can observe whether the relay 21 can be switched normally and whether its switching time is normal to detect the defective relay 21 on the carrier board 2.

In conclusion, the test apparatus 1 of the present disclosure is capable of performing directly the electrical test on the relay 21 on the carrier board 2. These electrical tests include the measurement of the ability of the relay 21 to switch in a normal manner, as well as the measurement of electrical values such as the operating/response time and release/reset time of the relay 21. As such, there is no need for desoldering or dismantling the relay 21 prior to performing electrical test. Consequently, the time required for addressing abnormal events during electronic component testing can be reduced, and the hazards associated with desoldering or dismantling the carrier board can be prevented.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A test cover, comprising:
a sleeve sleeve-coupled to a relay on a carrier board; and
a plurality of contacts disposed at an end of the sleeve and protruding from the sleeve, the plurality of contacts configured to contact and be electrically connected to a plurality of pins of the relay when the sleeve is sleeve-coupled to the relay for electrical testing of the relay on the carrier board.

2. The test cover of claim 1, wherein the sleeve is made of an antistatic material.

3. The test cover of claim 1, wherein each of the contacts of the test cover is in a shape of a post, a pin, or a cone.

4. The test cover of claim 1, wherein each of the contacts of the test cover is a pogo pin made of a conductive material.

5. The test cover of claim 1, wherein the plurality of contacts of the test cover are disposed at the end of the sleeve at locations corresponding to the plurality of pins of the relay, and wherein a quantity of the plurality of contacts of the test cover is equal to a quantity of the plurality of pins of the relay.

6. The test cover of claim 5, wherein each of the contacts of the test cover contacts and is electrically connected to a corresponding pin of the plurality of pins of the relay when the sleeve is sleeve-coupled to the relay.

7. The test cover of claim 1, wherein the plurality of pins of the relay are configured to be electrically connected to an electronic component socket and a test circuit on the carrier board.

8. A test apparatus, comprising:
a test device configured to perform an electrical test on a relay on a carrier board and to receive an electrical signal outputted from the relay during the electrical test;
an interface device electrically connected to the test device, the interface device configured to actuate the test device to perform the electrical test and to display the electrical signal; and
a test cover electrically connected to the test device, the test cover comprising:
a sleeve sleeve-coupled to the relay; and
a plurality of contacts disposed at an end of the sleeve and protruding from the sleeve, the plurality of contacts configured to contact and be electrically connected to a plurality of pins of the relay as the sleeve is sleeve-coupled to the relay for transmitting the electrical signal from the plurality of pins to the test device.

9. The test apparatus of claim 8, wherein the electrical test includes a measurement of whether the relay switches between an on state and an off state based on control of the test device, and wherein the electrical test includes a measurement of electrical values of the relay.

10. The test apparatus of claim 9, wherein the electrical values include an operating time and a release time of the relay.

11. The test apparatus of claim 8, wherein the test device controls the relay via the plurality of contacts of the test cover to perform the electrical test.

12. The test apparatus of claim 8, wherein the sleeve is made of an antistatic material.

13. The test apparatus of claim 8, wherein each of the contacts of the test cover is in a shape of a post, a pin, or a cone.

14. The test apparatus of claim 8, wherein each of the contacts of the test cover is a pogo pin made of a conductive material.

15. The test apparatus of claim 8, wherein the plurality of contacts of the test cover are disposed at the end of the sleeve at locations corresponding to the plurality of pins of the relay, and wherein a quantity of the plurality of contacts of the test cover is equal to a quantity of the plurality of pins of the relay.

16. The test apparatus of claim 15, wherein each of the contacts of the test cover contacts and is electrically connected to a corresponding pin of the plurality of pins of the relay when the sleeve is sleeve-coupled to the relay.

17. The test apparatus of claim 8, wherein the plurality of pins of the relay are configured to be electrically connected to an electronic component socket and a test circuit on the carrier board.
